(19) United States
(12) Patent Application Publication
(10) Pub. No.: US 2026/0231494 A1
(43) Pub. Date: Aug. 6, 2026

(54) DIAMOND AND SEMICONDUCTOR DEVICE

(71) Applicant: OOKUMA DIAMOND DEVICE Co., Ltd., Sapporo-shi, Hokkaido (JP)

(72) Inventors: Hiroyuki KAWASHIMA, Hokkaido (JP); Hitoshi UMEZAWA, Hokkaido (JP); Takahiro YAMAGUCHI, Hokkaido (JP); Naohisa HOSHIKAWA, Hokkaido (JP)

(21) Appl. No.: 19/159,081

(22) PCT Filed: Feb. 21, 2024
(86) PCT No.: PCT/JP2024/006341

§ 371 Date: Aug. 22, 2025

(30) Foreign Application Priority Data
Feb. 27, 2023 (JP) 2023-027994

(51) Int. Cl. H10D 62/83; H10D 30/60

(52) U.S. Cl. CPC H10D 62/8303; H10D 30/60

(57) ABSTRACT

Performance of a semiconductor device including an FET using diamond is improved. The present disclosure allows a diamond substrate 201 to function as a nitrogen-containing hydrogen-terminated diamond layer without providing a non-doped layer. In other words, in the present disclosure, the diamond substrate 201 is formed of a diamond layer which substantially contains nitrogen, is hydrogen-terminated, and has conductivity.

### TECHNICAL FIELD

The present invention relates to diamond and a semiconductor device.

### BACKGROUND ART

Japanese Patent Application Laid-open Publication No. 2017-092398 (Patent Document 1) discloses a technique related to a diamond electronic element having a diamond layer into which nitrogen is introduced.

### RELATED ART DOCUMENTS

### Patent Documents

Patent Document 1: Japanese Patent Application Laid-open Publication No. 2017-092398

### SUMMARY OF THE INVENTION

### Problems to be Solved by the Invention

For example, a field effect transistor (hereinafter, referred to as an FET in some cases) using a wide band gap semiconductor material having a band gap larger than that of silicon has excellent characteristics compared with an FET using silicon. Thus, an FET using a wide band gap semiconductor material is expected as a next-generation FET.

In this regard, diamond is a wide band gap semiconductor material having a band gap of 5.5 eV, and has excellent characteristics such as a high breakdown voltage, high thermal conductivity, and a high mobility. Thus, diamond is expected as a next generation wide band gap semiconductor material subsequent to silicon carbide (SiC) and gallium nitride (GaN).

However, an FET using diamond has a hurdle to be overcome from the viewpoint of improving performance, and measures to enable practical use is desired.

### Means for Solving the Problems

The diamond in one embodiment is a hydrogen-terminated diamond substantially containing nitrogen and having conductivity.

A semiconductor device according to an embodiment includes a field effect transistor. The field effect transistor includes a p-type diamond layer, a source electrode electrically connected to the p-type diamond layer, a drain electrode electrically connected to the p-type diamond layer, and a gate electrode provided between the source electrode and the drain electrode.

Here, the p-type diamond layer is a diamond layer that substantially contains nitrogen, is hydrogen-terminated, and has conductivity.

### Effects of the Invention

According to one embodiment, diamond having novel characteristics can be obtained, and performance of a semiconductor device including a field effect transistor using the diamond can be improved.

### BRIEF DESCRIPTIONS OF THE DRAWINGS

FIG. 1 is a diagram for describing a surface conduction type FET in the related art.

FIG. 2 is a cross-sectional view illustrating a configuration of a surface conduction type FET in an embodying aspect.

FIG. 3 is a cross-sectional view illustrating a configuration of a surface conduction type FET in an embodying aspect.

FIG. 4 is a diagram illustrating a planar measurement position in SIMS measurement.

FIG. 5 is a table illustrating a relationship between a nitrogen concentration and conductivity.

FIG. 6 is a graph illustrating a relationship between a nitrogen concentration and a threshold voltage.

FIG. 7 is a table illustrating a relationship between an applied device example, a threshold voltage, and a nitrogen concentration.

FIG. 8 is a graph illustrating drain current-drain voltage characteristics in a case where the nitrogen concentration is 2.5×10¹⁷/cm³

FIG. 9 is a diagram illustrating a configuration of a surface conduction type FET in a first modification example.

FIG. 10 is a diagram illustrating a configuration of a surface conduction type FET in a second modification example.

### DETAILED DESCRIPTION OF PREFERRED EMBODIMENTS

In all the drawings for describing the embodiments, the same members are denoted by the same reference numerals in principle, and repeated description thereof will be omitted. Note that hatching may be applied even in plan view for easy understanding of the drawings.

### <Usefulness of Diamond as Semiconductor Material>

For example, in the field of future mobile communications, satellite communications, or ultra-compact radar systems, or the like, an FET capable of high frequency transmission with high output is required. In this regard, semiconductor materials such as silicon (Si) and gallium arsenide (GaAs) reach a limit in output density at frequencies above several GHz. Thus, it has been examined to use wide band gap semiconductor materials such as silicon carbide (SiC), gallium nitride (GaN), and diamond in an FET. In particular, diamond has the highest thermal conductivity in materials (4 times than that of SiC, and 16 times than that of GaN) and the highest dielectric breakdown electric field strength in semiconductor materials (3 times than that of SiC and 10 times than that of GaN). The hole mobility and hole saturation velocity in diamond are equivalent to the electron mobility and electron saturation velocity in silicon.

From this, since the heat dissipation characteristic is excellent due to the high thermal conductivity of diamond, heat generation of a semiconductor device can be suppressed, and a high temperature operation of a semiconductor device can also be expected. In addition, since a semiconductor device is less likely to be destroyed even when a high voltage is applied due to the high dielectric breakdown electric field strength of diamond, diamond is suitable for a semiconductor device for high power applications. The high carrier mobility of diamond suggests that diamond has a high potential as a high-frequency semiconductor device.

From the above, it can be seen that diamond as a semiconductor material is promising for producing a next-generation semiconductor device including an FET capable of high output and high frequency transmission.

<Difficulty in Producing n-Type Diamond>

As described above, diamond is a wide band gap semiconductor material, and it is considered that n-type diamond can be produced by introducing n-type impurities called donors into diamond. Specifically, it is considered that n-type diamond can be realized by supplying electrons from a donor level of a donor to a conduction band of diamond.

Here, examples of the donor include nitrogen, but in diamond, the donor level of nitrogen does not exist in the vicinity of the conduction band but exists at a “deep level” away from the conduction band. Specifically, the donor level of nitrogen exists at an energy position of 1.7 eV lower than the conduction band of diamond. This indicates that in diamond, an activation energy for exciting electrons from the donor level of nitrogen to the conduction band of diamond is high.

Therefore, even when nitrogen as a donor is introduced into diamond, it is difficult to increase an amount of electrons supplied to the conduction band, and as a result, it is difficult to cause the diamond into which nitrogen is introduced to function as n-type diamond.

On the other hand, it is considered that p-type diamond can be produced by introducing a p-type impurity called an acceptor into diamond. Specifically, it is considered that p-type diamond can be produced by generating holes in a valence band of diamond by exciting electrons from a valence band of diamond to an acceptor level of an acceptor.

Here, examples of the acceptor include boron, and the acceptor level of boron exists in the vicinity of the valence band of diamond. Specifically, boron as an acceptor forms an acceptor level at an energy position of 0.37 eV higher than the valence band of diamond. That is, in diamond, the acceptor level of boron does not constitute a “deep level” like the donor level of nitrogen. Thus, the activation energy for exciting electrons from the valence band of diamond to the acceptor level of boron is not so large. As a result, in diamond, it is easier to realize to produce p-type diamond than to produce n-type diamond.

Therefore, as an FET manufactured by using diamond, a p-channel FET using p-type diamond which is easier to produce than n-type diamond is employed instead of an n-channel FET generally requiring n-type diamond. That is, an FET manufactured by using diamond is realized not as an FET using electrons as carriers but as an FET using holes as carriers. In particular, as an FET manufactured by using diamond, a p-channel FET called a “surface conduction type FET” exists. Hereinafter, the “surface conduction type FET” will be described.

### <Surface Conduction Type FET>

When diamond is hydrogen-terminated, there is a phenomenon in which holes (two-dimensional hole gas) are induced in the surface of the hydrogen-terminated diamond. An FET utilizing this phenomenon is a “surface conduction type FET”. That is, the “surface conduction type FET” is an FET in which a two-dimensional hole gas induced in the surface of hydrogen-terminated diamond is used for a channel of the FET, and conduction/non-conduction of the channel is controlled by changing a gate voltage applied to a gate electrode to perform a switching operation. According to this “surface conduction type FET”, it is possible to obtain an advantage of enabling a high-temperature operation with a high withstand voltage. This is because a “C—H” bond is formed by hydrogen terminating diamond, but this “C—H” bond is more stable than the “C—C” bond of diamond.

The mechanism of the phenomenon in which holes are induced in the surface of hydrogen-terminated diamond has not been completely elucidated, but two theories are considered to be likely.

First, one theory is a “transfer doping model”. This theory is that electrons present in the valence band of diamond move to a level determined by the chemical potential of the surface due to a difference in chemical potential caused by an adsorbent or a pH change of the surface, whereby holes are generated in the vicinity of the surface from which the electrons escape.

On the other hand, another theory is a “negative ion model”. The theory is as follows. That is, in the “C—H” bond generated due to hydrogen termination of diamond, hydrogen is positively charged while carbon is negatively charged due to a difference in electronegativity. As a result, negative ions in the atmosphere are adsorbed to positively charged hydrogen, and holes are attracted to the surface of diamond by the adsorbed negative ions.

As described above, although the mechanism has not been completely elucidated, a phenomenon occurs in which holes are actually induced in the surface of the hydrogen-terminated diamond. Utilizing this phenomenon enables an excellent FET that can operate at a high temperature with a high withstand voltage, which is a “surface conduction type FET”, to be realized.

Hereinafter, the related art of the “surface conduction type FET” will be described, and then room for improvement existing in the related art will be described.

### DESCRIPTION OF RELATED ART

The “related art” referred to in the present specification is a technology having a problem found by the present inventors although it is not a publicly known technology, and is a technology that is a premise of the present invention.

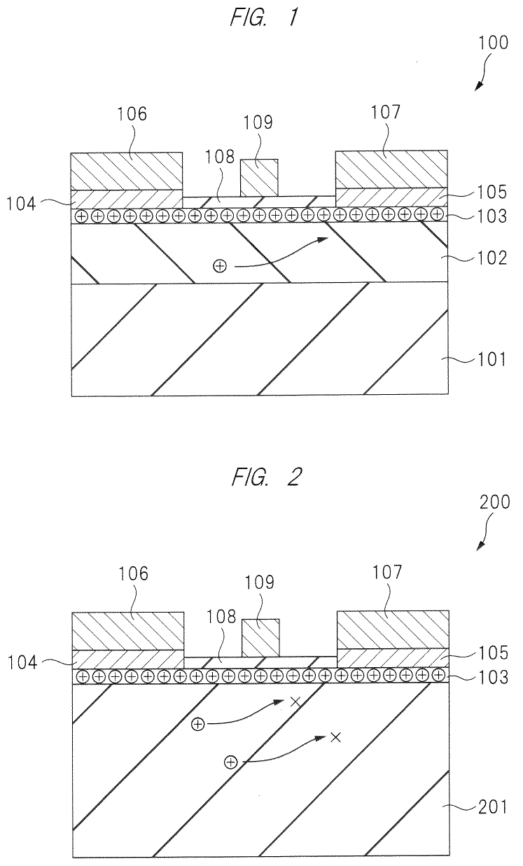

FIG. 1 is a diagram for describing a surface conduction type FET 100 in the related art.

In FIG. 1, the surface conduction type FET 100 has a diamond substrate 101 into which nitrogen is introduced, and a non-doped layer 102 is provided on the diamond substrate 101.

Here, the non-doped layer 102 mentioned in the present specification is a diamond layer in which a nitrogen impurity concentration is less than 10¹⁶/cm³, which is a lower detection limit of a measuring device using secondary ion mass spectrometry (SIMS).

The surface of the non-doped layer 102 is hydrogen-terminated. As a result, a hole accumulation layer 103 having a two-dimensional hole gas is formed in the surface of the non-doped layer 102.

Next, a contact layer 104 and a contact layer 105 that are separated from each other are provided on the non-doped layer 102. Each of the contact layer 104 and the contact layer 105 includes, for example, a pr-type diamond layer into which boron as a p-type impurity (acceptor) is introduced at a high concentration. Specifically, high-concentration boron is introduced into each of the contact layer 104 and the contact layer 105 to be in ohmic contact with the non-doped layer 102. A source electrode 106 is provided on the contact layer 104. On the other hand, a drain electrode 107 is provided on the contact layer 105.

Subsequently, a gate insulating film 108 is provided on the non-doped layer 102 between the contact layer 104 and the contact layer 105, and a gate electrode 109 is provided on the gate insulating film 108. The surface conduction type FET 100 is configured as described above.

Next, an operation of the surface conduction type FET 100 will be described.

The surface conduction type FET 100 is a p-channel type FET, and the hole accumulation layer 103 having a two-dimensional hole gas is formed in the vicinity of the surface of the non-doped layer 102. Here, in a state in which 0 V is applied to the gate electrode 109, for example, a positive potential is applied to the source electrode 106, and 0 V, which is a reference potential, is applied to the drain electrode 107. As a result, a hole current flows in a path including the source electrode 106, the contact layer 104, the hole accumulation layer (channel) 103 formed in the surface of the non-doped layer 102, the contact layer 105, and the drain electrode 107 in this order. That is, the surface conduction type FET 100 is a normally-on type FET.

Next, when a positive potential equal to or higher than the threshold voltage is applied to the gate electrode 109, a repulsive force acts on the two-dimensional hole gas formed immediately below the gate electrode 109 from the gate electrode 109 having a positive potential. As a result, the two-dimensional hole gas formed immediately below the gate electrode 109 is moved away from the vicinity of the surface of the non-doped layer 102. As a result, the channel including the two-dimensional hole gas disappears immediately below the gate electrode 109. In other words, when a positive potential equal to or higher than the threshold voltage is applied to the gate electrode 109, a depletion layer is formed immediately below the gate electrode 109, and the channel including the two-dimensional hole gas is blocked by the depletion layer. Thus, a hole current flowing through the hole accumulation layer 103 as a channel is cut off, and as a result, the surface conduction type FET 100 is turned off.

As described above, the switching operation (ON/OFF operation) of the surface conduction type FET 100 can be controlled by adjusting a gate voltage applied to the gate electrode 109. Therefore, in order to stabilize the switching operation of the surface conduction type FET 100, it is important to stabilize the threshold voltage of the gate voltage applied to the gate electrode 109.

### <Examination of Improvement>

In the above surface conduction type FET 100 of the related art, there is a large variation in the threshold voltage even for FETs of the same design. Thus, in the surface conduction type FET 100 of the related art, a switching operation cannot be stably controlled, or a current value at the time of ON differs depending on FETs. This is a major obstacle to practical use of the surface conduction type FET 100. That is, in the related art, a variation in threshold voltage, which is one of the most important characteristics of an FET, has become apparent as room for improvement.

In particular, the threshold voltage of the surface conduction type FET 100 greatly depends on a carrier density of the two-dimensional hole gas, and this carrier density is greatly affected by the “C—H” bond density. In this regard, the “C—H” bond density varies greatly depending on a state of a substrate or a layer such as surface roughness, and as a result, the threshold voltage varies greatly even for surface conduction type FETs 100 of the same design. That is, in the related art, it is difficult to stably control the threshold voltage since the threshold voltage depends on a difficult-to-control characteristic such as a “C—H” bond density of hydrogen termination. As described above, the surface conduction type FET 100 of the related art has room for improvement from the viewpoint of suppressing a variation in threshold voltage.

Since there is room for improvement in the related art, this point will be described.

In the related art, the non-doped layer 102 is employed as a layer in which diamond is hydrogen-terminated. The present inventors have newly found that the non-doped layer 102 includes not only a current that can be controlled by the gate electrode 109 due to the two-dimensional hole gas formed in the surface but also a current that is difficult to control by the gate electrode 109. Specifically, according to the examination of the present inventors, as illustrated in FIG. 1, it has become clear that a “deep current” that is difficult to control by the gate electrode 109 exists in a deep region away from the surface of the non-doped layer 102. The present inventors have newly found that the gain of the surface conduction type FET 100 is limited due to this “deep current”.

This point will be described below.

The gain of the surface conduction type FET is generally expressed by the following (Formula 1).

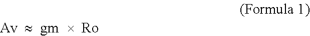

Av: gain (output gain)
gm: transconductance (transconductance)
Ro: output impedance

The output impedance can be calculated from a reciprocal of a slope of a Vd (drain voltage)-Id (drain current) curve in the saturation region.

Based on (Formula 1) described above, in order to increase the gain (Av), it is desirable to increase the transconductance (gm) and the output impedance (Ro). In this regard, the transconductance is increased in inverse proportion to the gate length of the gate electrode 109. That is, the transconductance can be increased by shortening the gate length of the gate electrode 109. However, when the gate length of the gate electrode 109 is shortened, the output impedance is likely to decrease due to a so-called short channel effect. That is, the transconductance and the output impedance tend to be in a trade-off relationship. As a result, there is an actual situation in which it is difficult to significantly improve the gain that is an output gain.

In this regard, the present inventors have newly found that the output impedance is decreased due to the above-described “deep current”. Therefore, if the “deep current” can be suppressed, it is considered that the output impedance can be increased. This indicates that while the transconductance is increased by shortening the gate length of the gate electrode 109, the output impedance is decreased due to the short channel effect, if a “deep current” which is one factor of decreasing the output impedance can be suppressed, the transconductance may be increased while the output impedance is maintained large. In this case, since the gain of the surface conduction type FET can be greatly improved, it is considered that there is a great technical significance for the development of the surface conduction type FET.

Therefore, the surface conduction type FET 100 of the related art has room for improvement from the viewpoint of suppressing a “deep current” in order to improve the gain.

From the above description, there is room for improvement in the related art from the viewpoint of suppressing a variation in threshold voltage and from the viewpoint of suppressing a “deep current”. Therefore, the present embodiment is devised to overcome the room for improvement existing in the related art. Hereinafter, the technical idea of the devised present embodiment will be described.

### Basic Idea in Embodiment

The basic idea in the present embodiment is an idea of providing, in place of the non-doped layer 102, a layer having a characteristic capable of controlling a threshold voltage and capable of generating a hole accumulation layer having a two-dimensional hole gas in the surface conduction type FET.

According to this basic idea, since the layer has a characteristic capable of controlling a threshold voltage, the threshold voltage can be stably controlled by adjusting this characteristic.

Specifically, the basic idea described above can be realized by providing a diamond layer substantially containing nitrogen and made of hydrogen-terminated diamond (hereinafter, referred to as a nitrogen-containing hydrogen-terminated diamond layer in some cases) instead of the non-doped layer 102. This is because the threshold voltage of the surface conduction type FET generally depends on a concentration of conductivity type impurity introduced into the diamond layer, and thus the threshold voltage can be stably controlled by adjusting the concentration of the conductivity type impurity.

For example, in a case where nitrogen is used as the conductivity type impurity, since the threshold voltage of the surface conduction type FET depends on the concentration of nitrogen introduced into the diamond layer, the threshold voltage can be stably controlled by adjusting the concentration of nitrogen. That is, the “characteristic capable of controlling the threshold voltage” of the basic idea is, for example, a concentration of nitrogen introduced into the diamond layer. As described above, the basic idea can be realized by providing a nitrogen-containing hydrogen-terminated diamond layer instead of the non-doped layer 102 in the surface conduction type FET.

Here, the term “substantially containing nitrogen” indicates that the nitrogen impurity concentration in the diamond layer is 10¹⁶/cm³ or more, which is the lower detection limit of a measuring device using “SIMS”. This term “substantially containing nitrogen” is intended to clarify a difference from the non-doped layer 102. That is, the non-doped layer 102 is defined as a diamond layer in which a nitrogen impurity concentration is 10¹⁶/cm³ or less, which is the lower detection limit of a measuring device using SIMS, in the diamond layer, and the term “substantially contains nitrogen” is used to clarify that the nitrogen-containing hydrogen-terminated diamond layer is a layer different from the non-doped layer 102.

For example, in the related art, the non-doped layer 102 in which a hole accumulation layer having a two-dimensional hole gas in the surface is formed through hydrogen termination is used, but the non-doped layer 102 does not have a characteristic capable of easily controlling the threshold voltage. This is because, for example, in the non-doped layer 102, since nitrogen exists only at a concentration equal to or lower than the detection limit, it is difficult to control the threshold voltage with the concentration of nitrogen. Thus, in the related art, since the threshold voltage of the surface conduction type FET depends on the characteristic of “C—H” bond density of hydrogen termination, which is difficult to control, it is difficult to stably control the threshold voltage.

On the other hand, according to the basic idea of the present embodiment, a nitrogen-containing hydrogen-terminated diamond layer is used instead of the non-doped layer 102. In this case, since the threshold voltage of the surface conduction type FET depends not only on the characteristic of “C—H” bond density of hydrogen termination, which is difficult to control, but also on the concentration of nitrogen introduced into the nitrogen-containing hydrogen-terminated diamond layer, the threshold voltage can be stably controlled by adjusting the concentration of nitrogen.

Therefore, the basic idea of providing a nitrogen-containing hydrogen-terminated diamond layer instead of the non-doped layer 102 is based on the characteristic (nitrogen concentration) capable of controlling the threshold voltage, and thus has a great technical significance in that the threshold voltage can be stably and easily controlled by adjusting this characteristic.

Here, according to conventional recognition, hydrogen-terminated diamond containing nitrogen is insulating, but the present inventors have found, as a novel finding, that a nitrogen-containing hydrogen-terminated diamond layer has conductivity depending on conditions, and the basic idea has been conceived on the basis of the novel finding. That is, since the nitrogen-containing hydrogen-terminated diamond layer has conductivity, a channel of a surface conduction type FET can be formed. As a result, the surface conduction type FET can be operated, and the basic idea is realized only when this novel finding is obtained.

The term “conductivity” mentioned in present specification indicates that a resistance value can be measured. For example, in a case where a sheet resistance value is measured to be MΩ/□ order or higher, the sheet resistance value often exceeds an upper measurement limit, and it is determined that a nitrogen-containing hydrogen-terminated diamond layer does not have conductivity. On the other hand, for example, in a case where a sheet resistance value is measured to be kΩ/□ order, the sheet resistance value can be measured, and it is determined that a nitrogen-containing hydrogen-terminated diamond layer has conductivity.

Hereinafter, the novel finding from which the above-described basic idea is conceived will be described.

### Novel Finding Found by Present Inventors

For example, with respect to diamond which is a wide band gap semiconductor material, nitrogen is a donor, but since the donor level of nitrogen is a “deep level”, it is recognized that diamond containing nitrogen does not have many electrons in the conduction band and is substantially an insulator.

The conventional recognition is that diamond which contains nitrogen and is hydrogen-terminated is also an insulator. This is because currently, for example, nitrogen at a concentration higher than 10¹⁸/cm³ is introduced into a commercially available diamond substrate, and holes included in a two-dimensional hole gas generated through hydrogen termination recombine with electrons excited in a conduction band due to high concentration nitrogen, and as a result, the two-dimensional hole gas is considered to disappear.

That is, even if the donor level of nitrogen is a “deep level”, electrons are slightly excited from the donor level to the conduction band of diamond, and some electrons exist in the conduction band. Therefore, it is conventionally recognized that as a result of recombination of electrons and holes existing in the conduction band, diamond containing nitrogen and hydrogen-terminated is also an insulator.

Due to this conventional recognition, in the related art, the non-doped layer 102 is used without using diamond containing nitrogen and hydrogen-terminated. That is, in the hydrogen-terminated non-doped layer 102, the two-dimensional hole gas is generated in the surface, but since the non-doped layer 102 contains almost no nitrogen, holes included in the two-dimensional hole gas do not recombine with electrons in the conduction band caused by nitrogen and do not completely disappear. Therefore, in the non-doped layer 102, the two-dimensional hole gas can be used for the channel of the surface conduction type FET.

From the above, based on the conventional recognition, it is found that the non-doped layer 102 needs to be provided on a commercially available diamond substrate. However, in this case, since the step of forming the non-doped layer 102 is added, this increases not only the number of manufacturing steps but also a variation in device performance typified by the threshold voltage. Thus, the non-doped layer 102 has been thinned. Finally, the present inventors confirmed that the surface conduction type FET is operated even if the non-doped layer 102 is not provided on a commercially available diamond substrate. This is because the performance of a commercially available diamond substrate has been improved, and the concentration of nitrogen contained in the diamond substrate has been reduced. That is, the present inventors have obtained, as a novel finding, the fact that when the concentration of nitrogen contained in the diamond substrate decreases to some extent through the above-described process, the conductivity caused by the two-dimensional hole gas generated through hydrogen termination can be secured even if the concentration of nitrogen does not decrease until the non-doped layer 102 is formed.

This novel finding can be understood by the qualitative mechanism described below. That is, a decrease in the nitrogen concentration of the diamond substrate indicates that the number of electrons excited in the conduction band of diamond is reduced, and thus the two-dimensional hole gas generated through the hydrogen termination does not completely disappear by recombination. As a result, since the two-dimensional hole gas remains in the surface of the hydrogen-terminated diamond substrate, it can be considered that conductivity is secured by the two-dimensional hole gas.

Based on the novel finding that a nitrogen-containing hydrogen-terminated diamond layer has conductivity depending on conditions, it has been found that it is possible to operate a surface conduction type FET even when a nitrogen-containing hydrogen-terminated diamond layer is used instead of the non-doped layer 102, and the basic idea has been conceived from the above novel finding.

The above novel finding suggests that surface conduction type FETs can be easily manufactured from commercially available diamond substrates in the future, and from this viewpoint as well, the novel finding found by the present inventors has important technical significance in practical use of surface conduction type FETs.

Hereinafter, an embodying aspect in which the above-described basic idea is embodied will be described.

### Embodying Aspect

### <<Configuration of Surface Conduction Type FET>>

FIG. 2 is a cross-sectional view illustrating a configuration of a surface conduction type FET 200 in an embodying aspect.

In FIG. 2, the surface conduction type FET 200 includes a diamond substrate 201 into which nitrogen is introduced. The surface of the diamond substrate 201 is hydrogen-terminated. That is, the diamond substrate 201 in the embodying aspect functions as a nitrogen-containing hydrogen-terminated diamond layer. In other words, the diamond substrate 201 is a p-type diamond layer. This p-type diamond layer, which substantially contains nitrogen, is a hydrogen-terminated diamond layer and is a diamond layer having conductivity. As described above, the surface of the diamond substrate 201 is hydrogen-terminated, so that a hole accumulation layer 103 including a two-dimensional hole gas is formed in the surface of the diamond substrate 201.

Next, a contact layer 104 and a contact layer 105 which are separated from each other are provided on the diamond substrate 201 having the hole accumulation layer 103. Each of the contact layer 104 and the contact layer 105 includes, for example, a p⁺-type diamond layer into which boron as a p-type impurity (acceptor) is introduced at a high concentration. Specifically, high-concentration boron is introduced into each of the contact layer 104 and the contact layer 105 to be in ohmic contact with the diamond substrate 201.

Specifically, the concentration of the boron is, for example, about 5×10¹⁹/cm³ or more and 1×10²²/cm³ or less. In addition, the thickness of each of the contact layer 104 and the contact layer 105 is, for example, about 20 nm or more and 300 nm or less.

A source electrode 106 is provided on the contact layer 104. On the other hand, a drain electrode 107 is provided on the contact layer 105. Subsequently, a gate insulating film 108 is provided on the diamond substrate 201 between the contact layer 104 and the contact layer 105, and a gate electrode 109 is provided on the gate insulating film 108.

Here, an electrode material of each of the source electrode 106, the drain electrode 107, and the gate electrode 109 is, for example, gold (Au), ruthenium (Ru), aluminum (Al), titanium (Ti), molybdenum (Mo), copper (Cu), chromium (Cr), lead (Pb), zinc (Zn), platinum (Pt), or a combination thereof (Ti/Mo/Au or the like). The thickness of each of the source electrode 106, the drain electrode 107, and the gate electrode 109 is, for example, about 10 nm to 100 nm.

On the other hand, the gate insulating film 108 is made of, for example, aluminum oxide (Al₂O₃), calcium fluoride (CaF₂), magnesium fluoride (MgF₂), silicon oxide (SiO₂), or silicon nitride (Si₃N₄). The film thickness of the gate insulating film 108 is, for example, about 5 nm or more and 100 nm or less.

The surface conduction type FET 200 configured as described above is a normally-on type FET. For example, as illustrated in FIG. 2, the gate electrode 109 does not overlap the contact layer 104, and the gate electrode 109 does not overlap the contact layer 105. Furthermore, in plan view, the gate electrode 109 does not overlap the contact layer 104, and in plan view, the gate electrode 109 does not overlap the contact layer 105.

The surface conduction type FET 200 is configured as described above.

### <<Operation of Surface Conduction Type FET>>

Next, an operation of the surface conduction type FET 200 will be described.

The surface conduction type FET 200 is a p-channel type FET, and the hole accumulation layer 103 having the two-dimensional hole gas is formed in the vicinity of the surface of the diamond substrate 201. Here, in a state in which 0 V is applied to the gate electrode 109, for example, a positive potential is applied to the source electrode 106, and 0 V, which is a reference potential, is applied to the drain electrode 107. As a result, a hole current flows in a path including the source electrode 106, the contact layer 104, the hole accumulation layer (channel) 103 formed in the surface of the diamond substrate 201, the contact layer 105, and the drain electrode 107 in this order. That is, the surface conduction type FET 200 is a normally-on type FET.

Next, when a positive potential equal to or higher than the threshold voltage is applied to the gate electrode 109, a repulsive force acts on the two-dimensional hole gas formed immediately below the gate electrode 109 from the gate electrode 109 having a positive potential. As a result, the two-dimensional hole gas formed immediately below the gate electrode 109 is moved away from the vicinity of the surface of the diamond substrate 201. As a result, the channel including the two-dimensional hole gas disappears immediately below the gate electrode 109.

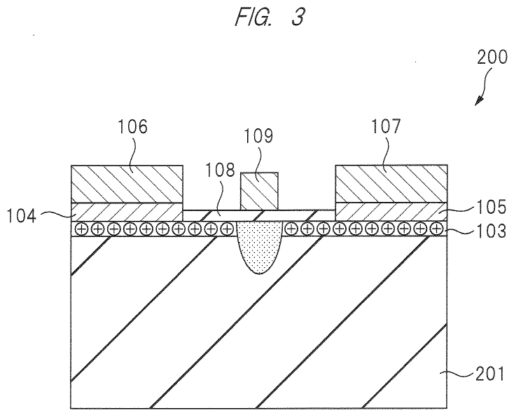

In other words, as illustrated in FIG. 3, when a positive potential equal to or higher than the threshold voltage is applied to the gate electrode 109, a depletion layer (dot region) is formed immediately below the gate electrode 109, and the channel including the two-dimensional hole gas is blocked by the depletion layer. Thus, a hole current flowing through the hole accumulation layer 103 as a channel is cut off, and as a result, the surface conduction type FET 100 is turned off.

As described above, a switching operation (ON/OFF operation) of the surface conduction type FET 200 can be controlled by adjusting a gate voltage applied to the gate electrode 109.

### Features in Embodying Aspect

Next, feature points in an embodying aspect will be described.

The first feature point is that the diamond substrate 201 functions as a nitrogen-containing hydrogen-terminated diamond layer without providing the non-doped layer 102. In other words, the first feature point is that diamond substrate 201 is formed of a diamond layer which substantially contains nitrogen, is hydrogen-terminated, and has conductivity. This makes it possible to realize a surface conduction type FET without using the non-doped layer 102.

Here, in order to impart conductivity to the nitrogen-containing hydrogen-terminated diamond layer, the concentration of nitrogen needs to be less than 1×10¹⁸/cm³. This is because, as a result of measuring the concentration of nitrogen with a SIMS measurement device, it has been found that only a nitrogen-containing hydrogen-terminated diamond layer having a concentration of nitrogen at less than 1×10¹⁸/cm³ has conductivity.

Examples of the technique of measuring the concentration of nitrogen include Fourier transform infrared spectroscopy (FTIR measurement), Hall effect measurement, and capacitance-voltage (CV) measurement in addition to SIMS measurement, and SIMS measurement results will be described below.

For example, when ions are incident on a sample surface, various particles such as electrons, neutral particles, and ions are emitted from the sample surface. The SIMS is a method of performing qualitative analysis and quantitative analysis of components contained in a sample by detecting ions among the particles and measuring a detection amount for mass of each ion. Specifically, the SIMS is a method in which when a sample surface is irradiated with primary ions such as oxygen or cesium, atoms in the vicinity of the sample surface are stirred, and some of the stirred atoms jump out into vacuum, and ions (secondary ions) of the particles that jump out are subjected to mass spectrometry to analyze components contained in the sample.

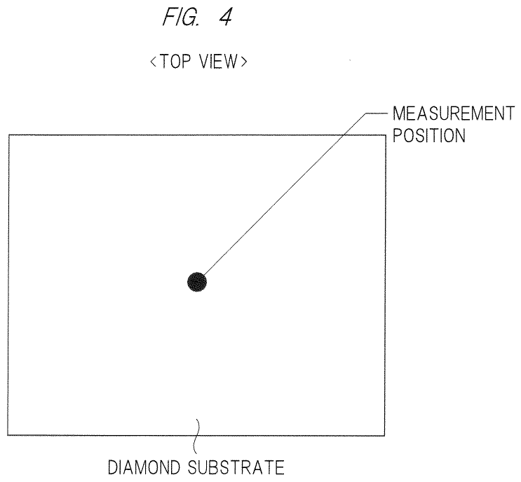

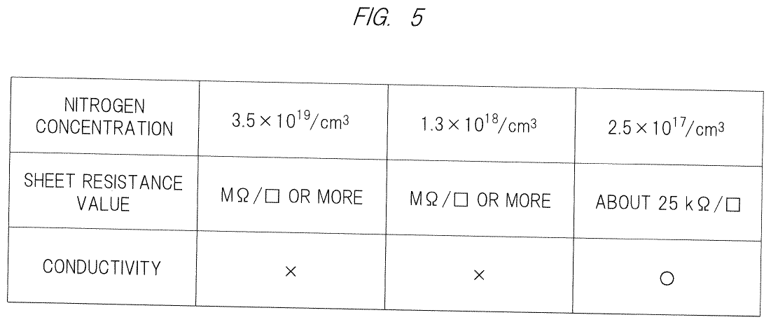

In the present embodiment, a nitrogen concentration contained in the diamond substrate is measured by using the SIMS under the following measurement conditions.
1. Implementation place: Japan Materials Science and Technology Foundation (MST)
2. Measurement conditions
(1) Measurement device: CAMECA IM-7f
(2) Primary ion species: Cs⁺
(3) Primary acceleration voltage: 15.0 kV
(4) Detection region: 30 (ump)
3. Measurement location
(1) Plane position: a position near the center of the diamond substrate (see FIG. 4)
(2) Depth: a range in which a stable value is measured without considering noise in the vicinity of the surface

In FIG. 4, the planar shape of the diamond substrate is a quadrangular shape, but this is merely an example, and the planar shape of the diamond substrate as a sample is not limited thereto, and may be a polygonal shape such as a pentagonal shape or a hexagonal shape, a circular shape including a perfect circle or an ellipse, or another shape including an irregular shape, and a planar measurement position in this case is a position near the center of each planar shape.

FIG. 5 is a table illustrating a relationship between a nitrogen concentration and conductivity.

In FIG. 5, it can be seen that when the nitrogen concentration is “3. 5×10¹⁹/cm³” or “1.3×10¹⁸/cm³”, the sheet resistance value is MΩ/□ more or which exceeds the upper measurement limit, and it does not have conductivity. On the other hand, it can be seen that when the nitrogen concentration is “2.5×10¹⁷/cm³”, the sheet resistance value is 25 kQ/D which included in the measurable range, and it has conductivity.

Therefore, based on the measurement results illustrated in FIG. 5, it can be seen that when the concentration of nitrogen is less than 1×10¹⁸/cm³, a nitrogen-containing hydrogen-terminated diamond layer has conductivity, and a surface conduction type FET can be realized without using the non-doped layer 102.

Further, according to the first feature point, since the nitrogen-containing hydrogen-terminated diamond layer is used, the threshold voltage of the surface conduction type FET depends on the concentration of nitrogen introduced into the nitrogen-containing hydrogen-terminated diamond layer. Therefore, according to the surface conduction type FET in the embodying aspect, the threshold voltage can be stably controlled by adjusting the concentration of nitrogen.

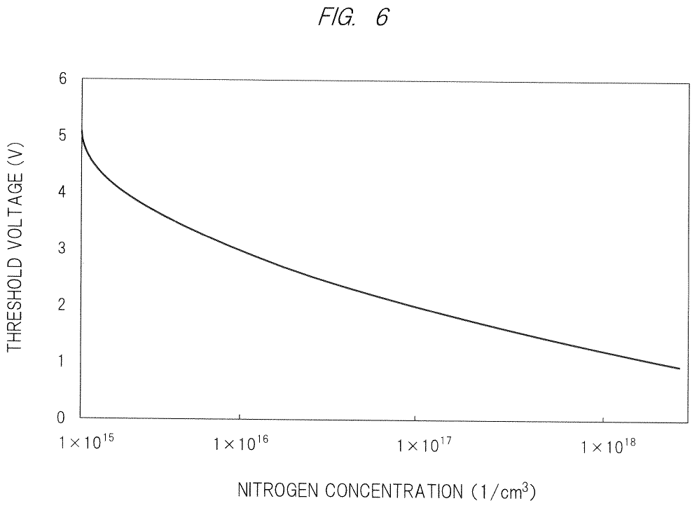

FIG. 6 is a graph illustrating a relationship between a nitrogen concentration and a threshold voltage. In FIG. 6, the horizontal axis represents a nitrogen concentration (1/cm³), and the vertical axis represents a threshold voltage (V).

Here, the nitrogen concentration of the nitrogen-containing hydrogen-terminated diamond layer having conductivity in the first feature point is less than 1×10¹⁸/cm³. Since the range of substantially containing nitrogen is 1×10¹⁶/cm³ or more, which is the lower measurement limit, the nitrogen concentration of the nitrogen-containing hydrogen-terminated diamond layer having conductivity in the first feature point is 1×10¹⁶/cm³ or more and less than 1×10¹⁸/cm³. On the other hand, the nitrogen concentration of the non-doped layer 102 is 1×10¹⁶/cm³ or less, which is the lower measurement limit or less. In view of this, referring to FIG. 6, it can be seen that in the range of 1×10¹⁶/cm³ or less, which is the nitrogen concentration of the non-doped layer 102, and in the range of 1×10¹⁶/cm³ or more and less than 1×10¹⁸/cm³, which is the nitrogen concentration of the nitrogen-containing hydrogen-terminated diamond layer having conductivity, a change in threshold voltage is gentler in the latter range than in the former range. This indicates that in the former nitrogen concentration range, the fluctuation in threshold voltage is large with respect to a slight fluctuation in the nitrogen concentration, while in the latter nitrogen concentration range, the fluctuation in the threshold voltage is small with respect to a slight fluctuation in the nitrogen concentration. Therefore, it can be seen that the surface conduction type FET using the nitrogen-containing hydrogen-terminated diamond layer having conductivity can reduce the variation in threshold voltage compared with the surface conduction type FET using the non-doped layer 102. As described above, according to the first feature point, it can be seen that the threshold voltage can be stably controlled.

According to the first feature point in the embodying aspect, the threshold voltage of the surface conduction type FET can be stably controlled by adjusting the nitrogen concentration. Thus, according to the embodying aspect, by using the technology of controlling the threshold voltage by adjusting the nitrogen concentration, surface conduction type FETs having the threshold voltage suitable for various applications can be separately manufactured.

This point will be described below.

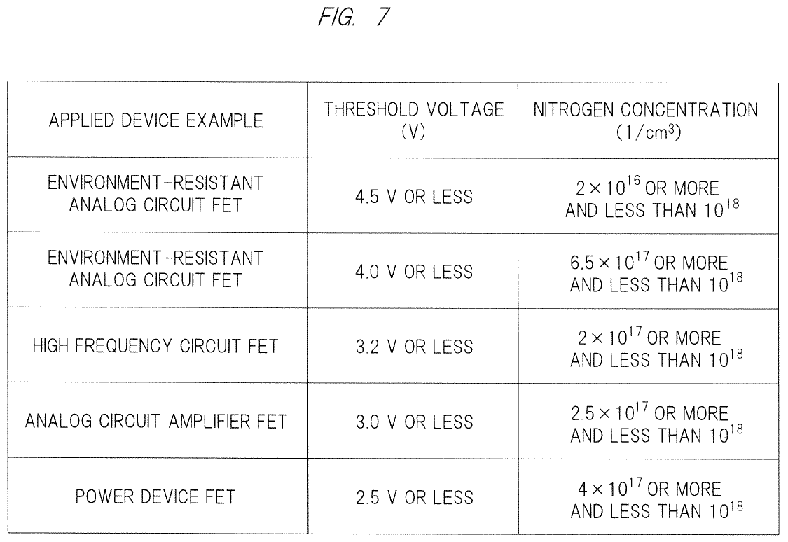

FIG. 7 is a table illustrating a relationship between an applied device example, a threshold voltage, and a nitrogen concentration.

In FIG. 7, for example, when an environment-resistant analog circuit FET is realized, 4.5 V or less is required as a threshold voltage, and thus the nitrogen concentration in this case is desirably 2×10¹⁶/cm³ or more and less than 1×10¹⁸/cm³.

Further, in a case where it is desired to keep the threshold voltage low in the environment-resistant analog circuit FET, 4.0 V or less is required as the threshold voltage. Therefore, the nitrogen concentration in this case is desirably 6.5×10¹⁶/cm³ or more and less than 1×10¹⁸/cm³.

For example, in the case of realizing a high frequency circuit FET, 3.2 V or less is required as a threshold voltage, and thus the nitrogen concentration in this case is desirably 2×10¹⁷/cm³ or more and less than 1×10¹⁸/cm³.

In addition, for example, in the case of realizing an analog circuit amplifier FET, 3.0 V or less is required as a threshold voltage, and thus the nitrogen concentration in this case is desirably 2.5×10¹⁷/cm³ or more and less than 1×10¹⁸/cm³.

For example, in the case of realizing a power device FET, 2.5 V or less is required as a threshold voltage, and thus the nitrogen concentration in this case is desirably 4×10¹⁷/cm³ or more and less than 1×10¹⁸/cm³.

As described above, according to the embodying aspect, surface conduction type FETs having threshold voltages suitable for various applications can be separately produced by adjusting the nitrogen concentration.

According to the embodying aspect, the threshold voltage of the surface conduction type FET can be controlled by adjusting the nitrogen concentration. In this regard, as a method of controlling the threshold voltage, in addition to the method of adjusting the nitrogen concentration, there are (1) a method of controlling the threshold voltage by changing a carrier concentration on the basis of a change in charge in a film or interface charge caused by the type or a formation condition of the gate insulating film or a structure (film thickness or the like) of the gate insulating film, (2) a method of controlling the threshold voltage by changing the work function instead of the material of the gate electrode, and the like, and the threshold voltage may be controlled by combining these methods.

Subsequently, according to the above-described first feature point, the following advantages can also be obtained.

For example, in the surface conduction type FET, a “deep current” is generated, and the “deep current” decreases the output impedance. In this regard, in an embodying aspect, the diamond substrate 201 is formed of a diamond layer which substantially contains nitrogen, is hydrogen-terminated, and has conductivity without providing the non-doped layer 102.

This indicates that, according to the first feature point, nitrogen is also introduced into the region where the “deep current” flows. Therefore, holes included in the “deep current” are likely to recombine with electrons excited from the donor level of nitrogen to the conduction band of diamond. As a result, according to the embodying aspect, the “deep current” can be suppressed.

Therefore, for example, while the transconductance is increased by shortening the gate length of the gate electrode 109, the output impedance is decreased due to the short channel effect. However, according to the first feature point, the “deep current”, which is one factor of decreasing the output impedance, can be suppressed. As a result, the transconductance can be increased while the output impedance is maintained large. Therefore, according to the first feature point in the embodying aspect, the gain of the surface conduction type FET can be greatly improved.

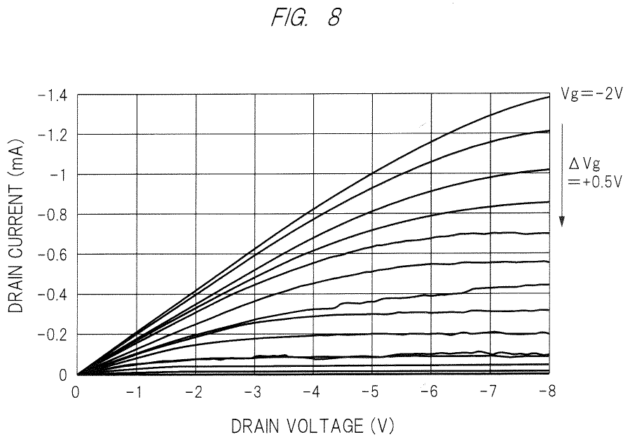

Specifically, FIG. 8 is a graph illustrating drain current-drain voltage characteristics in a case where the nitrogen concentration is 2.5×10¹⁷/cm³. In this graph, a curve illustrated at the top is a graph when the gate voltage Vg is-2 V, and curves illustrated below the top are graphs when the gate voltage is increased by ΔVg=+0.5 V.

For example, from FIG. 8, when the gate voltage Vg is −2 V, (1) the output impedance when nitrogen is added is 11 kΩ, whereas (2) the output impedance when nitrogen is not added is 8 kΩ. Therefore, from this result, it can be seen that the output impedance can be increased by adding nitrogen. That is, the output impedance can be increased as a result of suppressing the “deep current” according to the first feature point.

In order to improve the gain of the surface conduction type FET, it is desirable to increase the transconductance. In this regard, in order to increase the transconductance, it is effective to shorten the gate length of the gate electrode 109, but as a method of increasing the transconductance, there is also a method of reducing the parasitic resistance by reducing the space between the gate electrode 109 and the source electrode 106, and the transconductance may be increased by combining these methods.

According to the above first feature point, the following advantages can also be obtained.

For example, the non-doped layer 102 is formed on the diamond substrate 101, and the surface of the non-doped layer 102 is hydrogen-terminated, whereby a surface conduction type FET of the related art can be obtained. In this case, the non-doped layer 102 needs to be formed again on the commercially available diamond substrate 101, which complicates the manufacturing steps, and the non-doped layer 102 also becomes a factor of increasing variations in device characteristics. Therefore, improvement has been examined.

In this regard, in the first feature point in the embodying aspect, the diamond substrate 201 functions as a nitrogen-containing hydrogen-terminated diamond layer without providing the non-doped layer 102. That is, in an embodying aspect, the diamond substrate 201 is formed of a diamond layer which substantially contains nitrogen, is hydrogen-terminated, and has conductivity.

As a result, according to the embodying aspect, it is not necessary to form the non-doped layer 102 that causes complication of the manufacturing steps and increases variations in device characteristics.

That is, in a case where the nitrogen concentration of a commercially available diamond substrate is, for example, 1×10¹⁶/cm³ or more and less than 1×10¹⁸/cm³, hydrogen-terminating the commercially available diamond substrate enables the diamond substrate to function very easily as a nitrogen-containing hydrogen-terminated diamond layer having conductivity. This indicates that a surface conduction type FET can be easily manufactured from a commercially available diamond substrate, and has important technical significance in practical use (mass production) of the surface conduction type FET.

Subsequently, the second feature point in the embodying aspect is that, for example, as illustrated in FIG. 2, the gate electrode 109 does not overlap the contact layer 104, and the gate electrode 109 does not overlap the contact layer 105. Thus, the surface conduction type FET 200 having the second feature point can improve high frequency characteristics, and as a result, it is possible to provide a promising FET for realizing a next-generation semiconductor device including an FET capable of high frequency transmission.

This point will be described below.

For example, there is a normally-off type FET. The normally-off type FET is a type of FET in which the FET is turned off in a normal state (a state in which a gate voltage smaller than a threshold value is applied to the gate electrode), while the FET is turned on by applying a gate voltage equal to or higher than the threshold voltage to the gate electrode to form a channel called an inversion layer immediately below the gate electrode. In this normally-off type FET, it is necessary to exert a channel modulation effect from the gate electrode over the entire channel in order to form an inversion layer. Therefore, in the normally-off type FET, it is necessary to cause the gate electrode and the contact layer to overlap each other.

However, when the gate electrode and the contact layer overlap each other, parasitic capacitance is generated between the gate electrode and the source and between the gate electrode and the drain. This parasitic capacitance adversely affects the high frequency characteristics of the FET. Therefore, in the normally-off type FET, there is a hurdle to overcome in order to realize an FET capable of high frequency transmission.

On the other hand, the surface conduction type FET in the embodying aspect is a normally-on type FET. This normally-on type FET is a type of FET in which the FET is turned on and a current flows in a normal state (a state in which a gate voltage smaller than a threshold value is applied to a gate electrode), but when a gate voltage equal to or higher than the threshold voltage is applied to the gate electrode, a depletion layer extends from immediately below the gate electrode to cut off a channel, so that the FET is turned off.

In this normally-on type FET, it is not necessary to extend a depletion layer over the entire channel, and it is sufficient that a part of the channel immediately below the gate electrode can be blocked by the depletion layer. Therefore, it is not necessary to cause the gate electrode and the contact layer to overlap each other. Therefore, in the normally-on type FET, parasitic capacitance caused by overlapping of the gate electrode and the contact layer can be reduced, and as a result, frequency characteristics can be improved. Therefore, it can be seen that the normally-on type FET is more promising than the normally-off type FET in order to realize an FET capable of high frequency transmission.

### First Modification Example

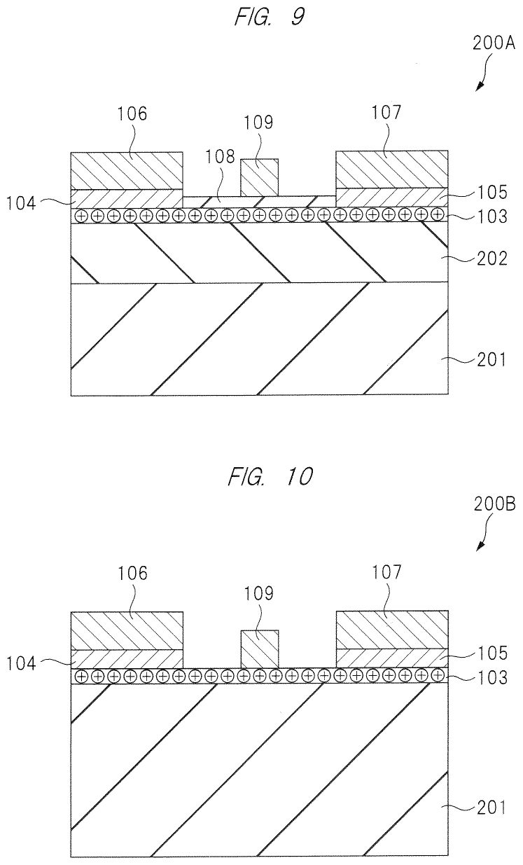

FIG. 9 is a diagram illustrating a configuration of a surface conduction type FET 200A in the first modification example.

In FIG. 9, in the surface conduction type FET 200A, a nitrogen-containing hydrogen-terminated diamond layer 202 is provided on a diamond substrate 201. As a result of hydrogen termination of the surface of the nitrogen-containing hydrogen-terminated diamond layer 202, a hole accumulation layer 103 containing a two-dimensional hole gas is formed in the surface. As described above, instead of causing the diamond substrate 201 itself to function as a nitrogen-containing hydrogen-terminated diamond layer, the nitrogen-containing hydrogen-terminated diamond layer 202 having conductivity may be provided on the diamond substrate 201.

In particular, the configuration of the first modification example is effective, for example, in a case where the concentration of nitrogen contained in the commercially available diamond substrate 201 is out of the range of 1×10¹⁶/cm³ or more and less than 1×10¹⁸/cm³. In this case, providing the nitrogen-containing hydrogen-terminated diamond layer 202 having a nitrogen concentration included in the range of 1×10¹⁶/cm³ or more and less than 1×10¹⁸/cm³ on the diamond substrate 201 enables a surface conduction type FET embodying the basic idea to be realized.

### Second Modification Example

FIG. 10 is a diagram illustrating a configuration of a surface conduction type FET 200B in the second modification example.

In FIG. 10, in the second modification example, the gate electrode 109 is in direct contact with the hole accumulation layer 103. In other words, a gate insulating film is not interposed between the gate electrode 109 and the hole accumulation layer 103. As described above, the gate electrode 109 may be in direct contact with the hole accumulation layer 103. In this case, for example, the gate electrode 109 and the hole accumulation layer 103 are in Schottky contact with each other. When a gate voltage equal to or higher than the threshold voltage is applied to the gate electrode 109, a depletion layer extends from immediately below the gate electrode 109, and the channel can be blocked.

Although the invention made by the present inventors has been specifically described on the basis of the embodiments, the present invention is not limited to the above embodiments, and it goes without saying that various modifications can be made within the scope without departing from the concept of the present invention.

### EXPLANATION OF REFERENCE CHARACTERS

100 Surface conduction type FET
200 Surface conduction type FET
200A Surface conduction type FET
200B Surface conduction type FET
101 Diamond substrate
102 Non-doped layer
103 Hole accumulation layer
104 Contact layer
105 Contact layer
106 Source electrode
107 Drain electrode
108 Gate insulating film
109 Gate electrode
201 Diamond substrate
202 Nitrogen-containing hydrogen-terminated diamond layer

1. Diamond substantially containing nitrogen and hydrogen-terminated,
wherein the diamond has conductivity.

2. The diamond according to claim 1,
wherein the substantially containing nitrogen indicates containing nitrogen at 1×10¹⁶/cm³ or more.

3. The diamond according to claim 1,
wherein the diamond is p-type diamond.

4. The diamond according to claim 1,
wherein a concentration of the nitrogen is less than 1×10¹⁸/cm³.

5. The diamond according to claim 1,
wherein a concentration of the nitrogen is 2×10¹⁶/cm³ or more and less than 1×10¹⁸/cm³.

6. The diamond according to claim 1,
wherein a concentration of the nitrogen is 6.5×10¹⁶/cm³ or more and less than 1×10¹⁸/cm³.

7. The diamond according to claim 1,
wherein a concentration of the nitrogen is 2×10¹⁷/cm³ or more and less than 1×10¹⁸/cm³.

8. The diamond according to claim 1,
wherein a concentration of the nitrogen is 2.5×10¹⁷/cm³ or more and less than 1×10¹⁸/cm³.

9. The diamond according to claim 1,
wherein a concentration of the nitrogen is 4×10¹⁷/cm³ or more and less than 1×10¹⁸/cm³.

10. A semiconductor device comprising a field effect transistor,
wherein the field effect transistor includes
a diamond layer,
a source electrode electrically connected to the diamond layer,
a drain electrode electrically connected to the diamond layer, and
a gate electrode provided between the source electrode and the drain electrode, and
wherein the diamond layer is a diamond layer that substantially contains nitrogen, is hydrogen-terminated, and has conductivity.

11. The semiconductor device according to claim 10,
wherein a gate insulating film is interposed between the diamond layer and the gate electrode.

12. The semiconductor device according to claim 10,
wherein the field effect transistor is a surface conduction type field effect transistor.

13. The semiconductor device according to claim 10,
wherein the field effect transistor is a normally-on type transistor.

14. The semiconductor device according to claim 10,
wherein the field effect transistor includes
a first contact layer provided between the diamond layer and the source electrode, and
a second contact layer provided between the diamond layer and the drain electrode.

15. The semiconductor device according to claim 14,
wherein, in plan view, the gate electrode does not overlap the first contact layer, and
wherein, in plan view, the gate electrode does not overlap the second contact layer.

16. A semiconductor device comprising a field effect transistor,
wherein the field effect transistor includes
a diamond layer,
a source electrode electrically connected to the diamond layer,
a drain electrode electrically connected to the diamond layer, and
a gate electrode provided between the source electrode and the drain electrode, and
wherein the diamond layer is made of the diamond according to claim 1.
